(19) United States
(12) Patent Application Publication
(10) Pub. No.: US 2023/0213389 A1
(43) Pub. Date: Jul. 6, 2023

(54) METHOD FOR MANUFACTURING A DETECTION DEVICE COMPRISING A PERIPHERAL WALL MADE OF A MINERAL MATERIAL

(71) Applicant: COMMISSARIAT A L'ENERGIE ATOMIQUE ET AUX ENERGIES ALTERNATIVES, Paris (FR)

(72) Inventors: Geoffroy DUMONT, Grenoble cedex 09 (FR); Jean-Jacques YON, Grenoble cedex 09 (FR)

(73) Assignee: COMMISSARIAT A L'ENERGIE ATOMIQUE ET AUX ENERGIES ALTERNATIVES, Paris (FR)

(21) Appl. No.: 17/996,125

(22) PCT Filed: Apr. 14, 2021
(86) PCT No.: PCT/EP2021/059701

§ 371 Date: Oct. 13, 2022

(30) Foreign Application Priority Data
Apr. 16, 2020 (FR) 2003858

(51) Int. Cl. G01J 5/04; G01J 5/10; G01J 5/02; B81B 7/00; B81C 1/00

(52) U.S. Cl. CPC G01J 5/045; G01J 5/10; G01J 5/046; G01J 5/0225; B81B 7/0051; B81C 1/00325; G01J 2005/106; B81B 2201/0278; B81B 2203/0127; B81C 2201/0109; B81C 2201/0133

(57) ABSTRACT

The invention relates to a method for fabricating a detection device, comprising the following steps: producing thermal detectors and an encapsulating structure by way of mineral sacrificial layers; partially removing the mineral sacrificial layers, by wet chemical etching in an acid medium, so as to free the thermal detectors and to obtain a peripheral wall, and to free an upper portion of the encapsulating thin layer; the peripheral wall then having a lateral recess resulting in a vertical enlargement of the cavity, between the readout substrate and the upper portion, this lateral recess defining an intermediate area; producing reinforcing pillars, arranged in the intermediate area around the matrix-array of thermal detectors.

### TECHNICAL FIELD

The field of the invention is that of devices for detecting electromagnetic radiation, in particular infrared or terahertz radiation, comprising at least one thermal detector encapsulated in a hermetic cavity. The invention is applicable in particular to the field of infrared imaging and thermography.

### PRIOR ART

A device for detecting electromagnetic radiation, for example infrared or terahertz radiation, may comprise a matrix-array of thermal detectors each comprising an absorbent portion able to absorb the electromagnetic radiation to be detected.

In order to ensure thermal insulation of the thermal detectors, the absorbent portions are usually in the form of membranes suspended above the substrate by anchoring pillars, and thermally insulated therefrom by holding and thermally insulating arms. These anchoring pillars and holding arms also have an electrical function, electrically connecting the suspended membranes to a readout circuit that is generally arranged in the substrate.

The readout circuit is usually in the form of a CMOS circuit. This allows the application of a control signal to the thermal detectors and the reading of detection signals generated thereby in response to the absorption of the electromagnetic radiation to be detected. The readout circuit comprises various electrical interconnection levels formed of metal lines that are separated from one another by what are known as inter-metal dielectric layers. At least one electrical connection pad of the readout circuit is arranged on the substrate such that it is able to be contacted from outside the detection device.

To ensure optimum operation of the thermal detectors, a low pressure level may be required. For this purpose, the matrix-array of thermal detectors is generally confined, or encapsulated, in a hermetic cavity under vacuum or at reduced pressure, this cavity being delimited, with the readout substrate, by an encapsulating structure.

Document EP3067674A2 describes one example of a method for fabricating a detection device 1, illustrated here in FIG. 1A, the thermal detectors 20 of which are arranged in a cavity 2. The method uses mineral sacrificial layers 61, 62 (shown here before they are removed) to produce the thermal detectors 20 and the encapsulating structure 30 defining the cavity 2, which are then removed by wet chemical etching. The encapsulating structure 30 is formed by one and the same thin layer A31, called encapsulating thin layer, which extends continuously above and around the thermal detectors and thus delimits the cavity 2 vertically and laterally. The encapsulating thin layer A31 is produced by conformal deposition on the upper face of the mineral sacrificial layer 62, and also in a peripheral trench that extends through the mineral sacrificial layers 61, 62 as far as the readout substrate 10. The encapsulating thin layer A31 is thus formed of an upper portion A31.1 that initially rests on the mineral sacrificial layer 62, and also a peripheral portion A31.2 that rests on the readout substrate 10 and laterally surrounds the thermal detectors 20. This configuration makes it possible in particular to reduce the bulk on the readout substrate 10 of the encapsulating structure 30.

Document WO2014/100648A1 describes another example of a method for fabricating a detection device 1, illustrated here in FIG. 1B, a thermal detector 20 of which is arranged in a cavity 2. The encapsulating structure 30 is formed by an encapsulating thin layer A31 that extends above the thermal detector 20, and by a peripheral wall A32 that continuously surrounds the thermal detector 20 and on which the encapsulating thin layer A31 rests. The peripheral wall A32 is formed by a non-etched portion of the sacrificial layers 61, 62. The peripheral wall A32 has a side face A32a that extends vertically along the axis Z. In other words, the side face A32a has an upper end Lₛᵤₚ in contact with the encapsulating thin layer A31 that is located perpendicular to the lower end L_{inf} in contact with the readout substrate 10.

However, there is a need to have a fabrication method in which the mechanical strength of the encapsulating structure is improved.

### DISCLOSURE OF THE INVENTION

The invention aims to propose a method for fabricating a detection device that makes it possible to improve the mechanical strength of the encapsulating structure, in particular limiting the risks of the encapsulating structure detaching at the edge of the cavity.

For this purpose, one subject of the invention is a method for fabricating a device for detecting electromagnetic radiation, comprising the following steps:
producing a matrix-array of thermal detectors able to detect the electromagnetic radiation, on a readout substrate, through a first mineral sacrificial layer, the thermal detectors and the first mineral sacrificial layer being covered by a second mineral sacrificial layer;
producing an encapsulating structure that delimits a cavity in which the matrix-array of thermal detectors is located, the encapsulating structure being formed of a peripheral wall and of an encapsulating thin layer, by:
   depositing the encapsulating thin layer covering the second mineral sacrificial layer;
   producing vents in the encapsulating thin layer, located facing the matrix-array of thermal detectors;
   partially removing the mineral sacrificial layers, by wet chemical etching in an acid medium, through the vents, so as to free the matrix-array of thermal detectors and to obtain the peripheral wall formed of a non-etched portion of the mineral sacrificial layers, and free an upper portion of the encapsulating thin layer extending above the matrix-array of thermal detectors.

According to the invention, due to the fact that the sacrificial layers are mineral and that the partial removal is carried out by wet chemical etching in an acid medium, following the chemical etching step, the peripheral wall has a lateral recess resulting in a vertical enlargement of the cavity, in a plane parallel to the plane of the readout substrate, between the readout substrate and the upper portion, this lateral recess defining an intermediate area of a surface of the readout substrate surrounding the matrix-array of thermal detectors.

The fabrication method then comprises a step of producing reinforcing pillars for the encapsulating thin layer, arranged in the intermediate area around the matrix-array of thermal detectors, separate from one another and extending from the upper portion until resting on the readout substrate.

Some preferred but non-limiting aspects of this fabrication method are as follows.

The peripheral wall may have a side face laterally delimiting the cavity, the side face extending vertically between a lower end in contact with the readout substrate and an upper end in contact with the upper portion, the upper end being spaced from the lower end, in a plane parallel to the plane of the readout substrate and in a direction opposite to the matrix-array of thermal detectors, by a distance greater than or equal to 10 μm.

The upper portion of the encapsulating thin layer may have a thickness less than or equal to 800 nm.

The reinforcing pillars may be arranged in multiple rows parallel to one another, which extend around the matrix-array of thermal detectors.

The thermal detectors may comprise an absorbent membrane suspended above the readout substrate by anchoring pillars. The reinforcing pillars may rest indirectly on the readout substrate, being in contact with lower pillars extending from the readout substrate, the lower pillars having the same height as that of the anchoring pillars.

The lower pillars may be anchoring pillars for what are known as dummy detectors not able to detect electromagnetic radiation, the anchoring pillars for each dummy detector holding a suspended membrane.

The dummy detectors may have a structure and dimensions identical to those of the thermal detectors of the matrix-array.

The encapsulating thin layer may comprise support pillars, arranged facing the matrix-array of thermal detectors, separate from one another and extending from the upper portion until resting on anchoring pillars for the thermal detectors, the anchoring pillars for each thermal detector holding a suspended membrane.

Insulating portions, made of an electrically insulating material, may be arranged between and in contact with the support pillars and the anchoring pillars for the thermal detectors.

The reinforcing pillars may rest directly on the readout substrate, being in contact with the readout substrate.

The encapsulating thin layer may comprise support pillars, separate from one another and extending from the upper portion until resting on and in contact with the readout substrate, each arranged between two adjacent thermal detectors.

The reinforcing pillars and the support pillars may have an identical structure and identical dimensions.

The encapsulating thin layer may comprise a peripheral portion, extending continuously around the matrix-array of thermal detectors, and arranged beyond the reinforcing pillars, in a plane parallel to the readout substrate and in a direction opposite to the matrix-array of thermal detectors, and extending from the upper portion in the direction of the readout substrate over part of the height of the cavity.

The wet chemical etching may be carried out with hydrofluoric acid in the vapor phase, and the mineral sacrificial layers may be made of a silicon-based material.

The invention also relates to a device for detecting electromagnetic radiation, comprising:
a readout substrate;
a matrix-array of thermal detectors, resting on the readout substrate;
an encapsulating structure, delimiting a cavity in which the matrix-array of thermal detectors is located, and comprising:
   a peripheral wall, made of a mineral material, and laterally delimiting the cavity;
   an encapsulating thin layer, comprising an upper portion extending above the matrix-array of thermal detectors and resting on the peripheral wall;
   the peripheral wall has a lateral recess resulting in a vertical enlargement of the cavity, in a plane parallel to the readout substrate, between the readout substrate and the upper portion, this lateral recess defining an intermediate area of a surface of the readout substrate surrounding the matrix-array of thermal detectors;
   the encapsulating thin layer comprises reinforcing pillars, arranged in the intermediate area around the matrix-array of thermal detectors, separate from one another and extending from the upper portion until resting on the readout substrate.

### BRIEF DESCRIPTION OF THE DRAWINGS

Other aspects, aims, advantages and features of the invention will become more clearly apparent on reading the following detailed description of preferred embodiments thereof, given by way of non-limiting example and with reference to the appended drawings, in which:

FIGS. 1A and 1B are cross-sectional, schematic and partial views of two detection devices according to examples from the prior art, illustrating various configurations of the encapsulating structure defining the cavity;

FIGS. 2A to 2F are cross-sectional, schematic and partial views of various steps of a method for fabricating a detection device according to a first embodiment in which the encapsulating thin layer comprises reinforcing pillars resting on anchoring pillars for dummy detectors;

FIG. 3A is a plan, schematic and partial view of a detection device according to one variant of the first embodiment;

FIG. 3B is a cross-sectional, schematic and partial view of a detection device according to another variant of the first embodiment, in which the encapsulating thin layer comprises a peripheral portion;

FIG. 3C is a cross-sectional, schematic and partial view of a detection device according to another variant of the first embodiment, in which the reinforcing pillars for the encapsulating thin layer rest on lower pillars;

FIG. 4A is a cross-sectional, schematic and partial view of a detection device according to a second embodiment, in which the reinforcing pillars for the encapsulating thin layer are hollow pillars that rest in contact with the readout substrate;

FIG. 4B is a cross-sectional, schematic and partial view of a detection device according to one variant of the second embodiment, in which the reinforcing pillars for the encapsulating thin layer are solid pillars;

FIG. 4C is a plan, schematic and partial view of a detection device according to another variant of the second embodiment.

### DETAILED DISCLOSURE OF PARTICULAR EMBODIMENTS

In the figures and in the remainder of the description, the same references represent identical or similar elements. In addition, the various elements are not shown to scale so as to make the figures clearer. Furthermore, the various embodiments and variants are not mutually exclusive, and may be combined with one another. Unless indicated otherwise, the terms “substantially”, “approximately” and “of the order of” mean to within 10%, and preferably to within 5%. Furthermore, the terms “between . . . and . . . ” and the like mean that the bounds are included, unless stated otherwise.

The invention relates in general to a method for fabricating an electromagnetic radiation detection device able to detect infrared or terahertz radiation.

This detection device comprises a matrix-array of thermal detectors located in a hermetic cavity. The matrix-array of thermal detectors forms a preferably periodic array. Each of the thermal detectors is an optically sensitive detector, and forms a detection pixel able to detect the electromagnetic radiation of interest.

The fabrication method comprises a step of producing the matrix-array of thermal detectors by way of what are called mineral sacrificial layers, made of a mineral or inorganic material, these sacrificial layers being intended to form the peripheral wall mentioned above. This is a silicon-based dielectric material that also makes it possible to produce an inter-metal dielectric layer of the readout circuit, that is to say an electrically insulating material, with for example a dielectric constant, or relative permittivity, less than or equal to 3.9, thus limiting parasitic capacitance between the interconnects. This mineral material does not contain any carbon chains, and may be a silicon oxide SiOₓ or a silicon nitride SiₓN_{y}, or even an organosilicon material such as SiOC, SiOCH, or a fluoride glass-type material such as SiOF. It is preferably a silicon oxide SiOₓ.

The fabrication method also comprises a step of partially removing the mineral sacrificial layers by wet chemical etching in an acid medium, for example with hydrofluoric acid in the vapor phase (HF vapor). Wet etching is generally understood to mean that the etching agent is in the liquid phase or in the vapor phase, and here, preferably, in the vapor phase.

The hermetic cavity is delimited by an encapsulating structure that comprises:
multiple thin layers transparent to the electromagnetic radiation to be detected, including in particular an encapsulating thin layer, an upper portion of which extends above the matrix-array of thermal detectors and vertically delimits the cavity, and a thin layer for sealing the vents 33;
a peripheral wall that extends continuously around the matrix-array of thermal detectors and laterally delimits the cavity. As explained further below, the peripheral wall is formed of a non-etched portion of mineral sacrificial layers.

A thin layer is understood to mean a layer formed by microelectronic material deposition techniques, the thickness of which is preferably less than or equal to 10 μm. Furthermore, a thin layer is said to be transparent when it has a transmission coefficient greater than or equal to 50%, preferably 75%, or even 90% for a center wavelength of the spectral range of the electromagnetic radiation to be detected.

As described further below, following the wet chemical etching step, the peripheral wall has a lateral cavity resulting in a vertical enlargement of the cavity between the readout substrate and the upper portion, in a plane parallel to the plane of the readout substrate. The cavity then has a flared shape in a vertical direction +Z opposite to the readout substrate. In other words, the cavity is wider at the upper portion than at the readout substrate. The peripheral wall is therefore further from the matrix-array of thermal detectors at the upper portion than at the readout substrate.

This lateral recess in the peripheral wall extends around the matrix-array of thermal detectors, in a plane XY parallel to the readout substrate, thus defining an intermediate area Zr, called reinforcement area for reinforcing the surface of the readout substrate. In this recessed area, the encapsulating thin layer comprises reinforcing pillars, separate from one another and resting on the readout substrate, and arranged around the matrix-array of thermal detectors. These reinforcing pillars make it possible to increase the mechanical strength of the encapsulating structure, and in particular to prevent the upper portion from detaching from the peripheral wall. These reinforcing pillars may have various configurations:
according to a first embodiment, they rest indirectly on the readout substrate, for example resting on the anchoring pillars for dummy detectors or on lower pillars;
according to a second embodiment, they rest directly on the readout substrate, then coming into contact with the readout substrate.

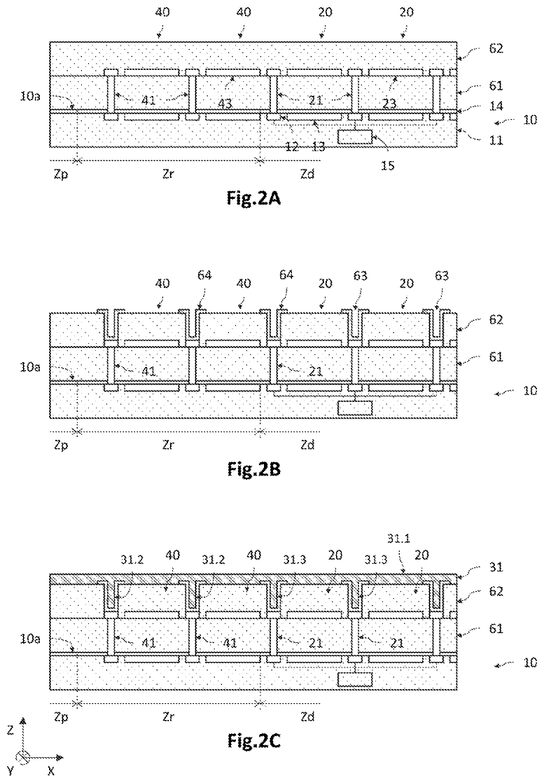

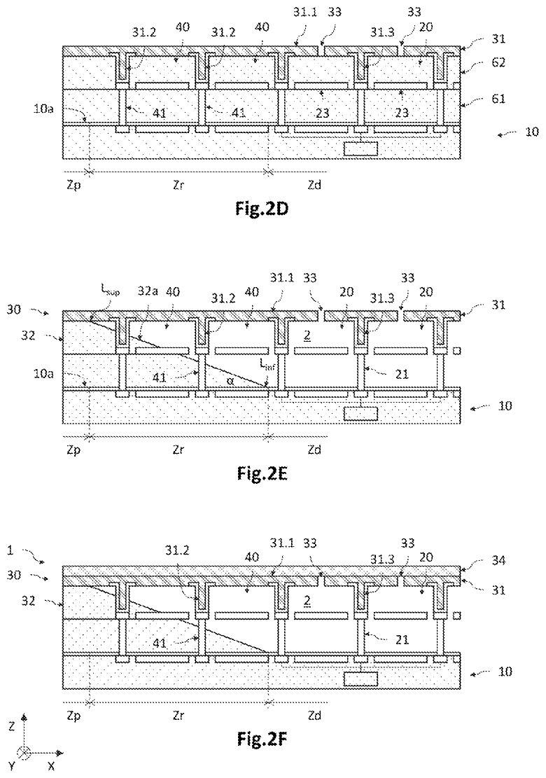

FIGS. 2A to 2G illustrate various steps of a method for fabricating a detection device 1 according to a first embodiment in which the reinforcing pillars 31.2 of the encapsulating thin layer 31 rest indirectly on the readout substrate 10, here via anchoring pillars 41 for dummy detectors 40 produced in the reinforcement area Zr. For the sake of clarity, only part of the detection device 1 is shown in the figures.

The detection device 1 comprises a matrix-array of what are called sensitive thermal detectors 20, located in a hermetic cavity 2 defined by an encapsulating structure 30. As described below, the encapsulating structure 30 comprises an encapsulating thin layer 31 of which an upper portion 31.1 extends above the matrix-array of thermal detectors 20 and rests on a peripheral wall 32 formed of a non-etched portion of the mineral sacrificial layers 61, 62. The encapsulating thin layer 31 comprises reinforcing pillars 31.2, located in an intermediate area Zr, called reinforcement area, around the matrix-array of thermal detectors 20, which rest on the readout substrate 10, here via anchoring pillars 41 for dummy detectors 40.

By way of example, the sensitive thermal detectors 20 (that is to say the detectors of the matrix-array) are able here to detect infrared radiation in the LWIR (Long Wavelength Infrared) range, the wavelength of which is between approximately 8 μm and 14 μm. They are structurally identical to one another here, and are connected to a readout circuit 15 located in the substrate (then called readout substrate 10). The sensitive thermal detectors 20 thus form sensitive pixels preferably arranged periodically, and may have a lateral dimension in the plane of the readout substrate 10 of the order of a few tens of microns, for example equal to approximately 10 μm or even less.

A direct three-dimensional reference system XYZ is defined here and hereinafter, where the plane XY is substantially parallel to the plane of the readout substrate 10, the axis Z being oriented in a direction substantially orthogonal to the plane of the readout substrate 10 in the direction of the thermal detectors 20. The terms “vertical” and “vertically” are understood to relate to an orientation substantially parallel to the axis Z, and the terms “horizontal” and “horizontally” are understood to relate to an orientation substantially parallel to the plane (X,Y). Furthermore, the terms “lower” and “upper” are understood to relate to a position that increases moving away from the readout substrate 10 in the direction +Z.

With reference to FIG. 2A, the matrix-array of thermal detectors 20 is produced on the readout substrate 10 by way of a first mineral sacrificial layer 61, these thermal detectors 20 being covered by a second mineral sacrificial layer 62. In this example, multiple what are called dummy detectors 40 are also produced. As explained below, the thermal detectors 20 of the matrix-array are sensitive (optically active) detectors intended to supply an electrical signal in response to the detection of the electromagnetic radiation of interest. On the other hand, the dummy detectors 40 are not sensitive detectors in the sense that they do not supply the readout circuit with an electrical signal representative of the electromagnetic radiation to be detected.

The readout substrate 10 is made from silicon, and is formed of a support substrate 11 containing the readout circuit 15 able to control and read the sensitive thermal detectors 20. It might not be able to control and read the dummy detectors 40. The readout circuit 15 here is the form of a CMOS integrated circuit. It comprises, inter alia, portions of conductive lines that are separated from one another by inter-metal insulating layers made of a dielectric material, for example a silicon-based mineral material such as a silicon oxide SiOₓ, a silicon nitride SiNₓ, inter alia. Conductive portions are flush with the surface of the support substrate 11, and ensure the electrical connection of the anchoring pillars 21 for the sensitive thermal detectors 20 to the readout circuit. In addition, one or more connecting portions 12 (not shown) are flush with the surface of the support substrate 11, and make it possible to connect the readout circuit 15 to an external electronic device. As a variant, the readout circuit 15 may be able to read an electrical signal emitted by the dummy detectors 40, in particular when these are able to supply an electrical signal representative of the temperature of the readout substrate 10.

The readout substrate 10 may comprise a reflector 13 arranged facing each sensitive detector 20. The reflector 13 may be formed by a portion of a conductive line of the last interconnection level, said line being made of a material able to reflect the electromagnetic radiation to be detected. It extends facing the absorbent membrane 23 of the sensitive detector 20, and is intended to form therewith a quarter-wave interference cavity with respect to the electromagnetic radiation to be detected.

Finally, the readout substrate 10 here comprises a protective layer 14 so as to cover in particular the upper inter-metal insulating layer. This protective layer 14 corresponds here to an etch stop layer made of a material substantially inert to the chemical etching agent subsequently used to remove the various mineral sacrificial layers 61, 62, for example with HF medium in the vapor phase. This protective layer 14 thus forms a hermetic and chemically inert layer, which is electrically insulating so as to prevent any short circuit between the anchoring pillars 21. It thus makes it possible to prevent the underlying inter-metal insulating layers from being etched during this step of removing the mineral sacrificial layers. It may be formed from an aluminum oxide or nitride, or even from aluminum trifluoride, or else from non-intentionally doped amorphous silicon.

The sensitive thermal detectors 20 are then produced on the readout substrate 10, along with, in this example, the dummy detectors 40. These production steps are identical or similar to those described in particular in document EP3239670A1. The sensitive thermal detectors 20 and the dummy detectors 40 here advantageously have the same structure. They are in this case microbolometers each comprising an absorbent membrane 23, 43, that is to say capable of absorbing the electromagnetic radiation to be detected, suspended above the readout substrate 10 by anchoring pillars 21, 41, and thermally insulated therefrom by holding and thermally insulating arms (not shown). Absorbent membranes 23, 43 are conventionally obtained through surface micro-machining techniques consisting in producing the anchoring pillars 21, 41 through a first mineral sacrificial layer 61, and the thermally insulating arms along with the absorbent membranes 23, 43 on the upper face of the mineral sacrificial layer 61. Each absorbent membrane 23, 43 furthermore comprises a thermometric transducer, for example a thermistor material, connected to the readout circuit by electrical connections provided in the thermally insulating arms and in the anchoring pillars. The absorbent membrane 43 might, as a variant, not comprise a thermometric transducer. Furthermore, the holding arms for the absorbent membrane 43 might not comprise electrical connectors connecting the thermometric transducer to the readout circuit 15.

The thermal detectors 20 of the matrix-array are sensitive (optically active) detectors, that is to say they are able to detect the electromagnetic radiation of interest and are electrically connected to the readout circuit present in the readout substrate 10. They each form a detection pixel. On the other hand, the dummy detectors 40 are not intended to supply an electrical signal representative of the received electromagnetic radiation. They then might not be electrically connected to the readout circuit 15 (but they could be). As described further below, the dummy detectors 40, and in particular their anchoring pillars 41, are intended to contribute to the mechanical reinforcement of the encapsulating structure 30.

The sensitive thermal detectors 20 are located in a central area, called detection area Zd, of the surface 10a of the readout substrate 10, and the dummy detectors 40 are located in an intermediate area, called reinforcement area Zr, of this surface 10a, which continuously surrounds the detection area Zd in the plane XY. More precisely, multiple areas are defined within the surface 10a of the readout substrate 10:
a central area Zd, called detection area, in which the matrix-array of (sensitive) thermal detectors 20, that is to say the detection pixels, is located. The surface 10a of the readout substrate 10 in the detection area Zd is intended to be entirely freed from the mineral sacrificial layers 61, 62;
an intermediate reinforcement area Zr, which continuously surrounds the detection area Zd in the plane XY, and in which the reinforcing pillars 31.2 of the encapsulating thin layer 31, and, in this embodiment, also the dummy detectors 40, are intended to be located. It will be at least partially covered by the partially etched mineral sacrificial layers 61, 62;
a peripheral area Zp, which continuously surrounds the reinforcement area Zr in the plane XY, and in which the upper portion 31.1 of the encapsulating thin layer 31 is intended to rest in contact with the peripheral wall 32 (the latter being formed by the non-etched portions of the mineral sacrificial layers 61, 62).

A second mineral sacrificial layer 62 is then deposited, preferably of the same kind as the mineral sacrificial layer 61. The mineral sacrificial layer 62 thus covers the mineral sacrificial layer 61 and also the sensitive detectors 20 and the dummy detectors 40. It has a substantially planar upper face, opposite to the readout substrate 10 along the axis Z. In general, the various mineral sacrificial layers 61, 62 may be a silicon oxide obtained from a TEOS (tetraethyl orthosilicate) compound deposited by PECVD.

With reference to FIG. 2B, multiple indentations 63 (vias) are produced so as to allow the production of reinforcing pillars 31.2 of an encapsulating thin layer 31 of the encapsulating structure 30. These indentations 63 extend from the upper face of the mineral sacrificial layer 62 along the axis Z so as to open out onto at least some of the anchoring pillars 41 for the dummy detectors 40. In this example, indentations intended to allow the production of support pillars 31.3 of the encapsulating thin layer 31 are also produced, these indentations opening out onto the anchoring pillars 21 for the sensitive detectors 20. It should be noted here that, in this embodiment, the encapsulating thin layer 31 will comprise reinforcing pillars 31.2 resting on the anchoring pillars 41 for the dummy detectors 40, and also support pillars 31.3 resting on the anchoring pillars 21 for the sensitive detectors 20. The support pillars 31.3 and the reinforcing pillars 31.2 advantageously have one and the same structure and the same dimensions, and differ from one another in that the former are arranged in the detection area Zd while the latter are arranged in the reinforcement area Zr.

Next, advantageously, a plurality of insulating portions 64 are produced in the indentations opening out onto the anchoring pillars 21 for the sensitive detectors 20, and, to obtain the same grip on all of the pillars, preferably also in the indentations opening out onto the anchoring pillars 41 for the dummy detectors 40. These insulating portions 64 are portions of a thin layer made of an electrically insulating material. They make it possible to prevent an electrical short circuit between the sensitive detectors 20 and the encapsulating thin layer 31 via its support pillars 31.3, and if necessary via the reinforcing pillars 31.2. For this purpose, an insulating thin layer is deposited on the freed surface of the anchoring pillars 21, 41 inside the indentations. The insulating thin layer here is advantageously etched locally facing the sensitive detectors 20, so as not to reduce the transmission of the electromagnetic radiation to be detected, but it might not be etched. It may have a thickness of between approximately 10 nm and 100 nm. It is made of a material inert to the wet chemical etching implemented when removing the mineral sacrificial layers, which may be chosen from among AlN, Al₂O₃, HfO₂.

With reference to FIG. 2C, the encapsulating thin layer 31 of the encapsulating structure 30 is produced, this encapsulating thin layer 31 having reinforcing pillars 31.2, separate from one another and located in the reinforcement area Zr, resting on the readout substrate 10 via the anchoring pillars 41 for the dummy detectors 40. In this example, the encapsulating thin layer 31 also comprises support pillars 31.3 resting on the readout substrate 10 via the anchoring pillars 21 for the sensitive detectors 20.

For this purpose, the conformal deposition of the encapsulating thin layer 31 is carried out, this thin layer being made of a material transparent to the electromagnetic radiation of interest and inert to the wet chemical etching implemented subsequently, with a thickness of for example between 200 nm and 2 μm, for example equal to approximately 800 nm or even less, for example amorphous silicon, amorphous germanium, an amorphous silicon-germanium alloy, inter alia. The encapsulating thin layer 31 is deposited on the mineral sacrificial layer 62 and also in the indentations 63, for example using a chemical vapor deposition (CVD) technique.

The encapsulating thin layer 31 thus comprises the following, formed in one piece:
an upper portion 31.1, substantially planar in the plane XY, which extends above and at a distance along the axis Z from the sensitive detectors 20 and the dummy detectors 40, and covers the mineral sacrificial layer 62;
a plurality of reinforcing pillars 31.2, formed in one piece with the upper portion 31.1, which extend along the axis Z from the upper portion 31.1 in the indentations 63 to the anchoring pillars 41 for the dummy detectors 40. The reinforcing pillars 31.2 are located in the reinforcement area Zr.
advantageously, a plurality of support pillars 31.3, formed in one piece with the upper portion 31.1, which extend along the axis Z from the upper portion 31.1 in the indentations to the anchoring pillars for the sensitive detectors 20. The support pillars 31.3 are located in the detection area Zd.

The support pillars 31.3 and reinforcing pillars 31.2 have dimensions in the plane XY of the order of those of the anchoring pillars 21, 41. The anchoring pillars 21, 41 may thus each comprise a vertical portion having dimensions in the plane XY of the order of 0.5 μm to 1 μm topped by an upper portion 31.1 projecting laterally by the order of 0.2 μm to 0.5 μm with respect to the vertical portion. The support pillars 31.3 and reinforcing pillars 31.2 here may have dimensions in the plane XY of the order of approximately 0.5 μm to 2 μm.

Unlike in document EP3239670A1, the encapsulating thin layer 31 does not comprise a peripheral wall that laterally delimits the cavity 2, that is to say a peripheral wall of the encapsulating thin layer 31 that would extend to the readout substrate 10 and continuously surrounds the matrix-array of thermal detectors 20 in the plane XY. In the context of the invention, the peripheral wall 32 is made from a non-etched portion of the mineral sacrificial layers 61, 62 and not from the material of the encapsulating thin layer 31.

With reference to FIG. 2D, the vents 33 are produced through the encapsulating thin layer 31. These vents 33 open out onto the mineral sacrificial layer 62 and are intended to allow the evacuation of the various mineral sacrificial layers 61, 62 out of the cavity 2. They are arranged only facing the detection area Zd, and are therefore not located facing the reinforcement area Zr or the peripheral area Zp. They will thus make it possible to completely free the surface 10a of the readout substrate 10 in the detection area Zd, and to form the peripheral wall 32. In this example, the vents 33 are located perpendicular to the absorbent membranes 23 of all or some of the sensitive thermal detectors 20, but they may be arranged differently, in particular perpendicular to their anchoring pillars 21. The vents 33 may have various shapes in the plane XY, for example a circular shape with a diameter of 0.4 μm or even less.

With reference to FIG. 2E, chemical etching is carried out, which is able to partially remove the mineral sacrificial layers 61, 62 from the vents 33. The chemical etching is wet etching in an acid medium, for example with hydrofluoric acid in the vapor phase. The products of the chemical reaction are evacuated through the vents 33.

Due to the arrangement of the vents 33 facing only the detection area Zd, the etching agent fully removes the mineral sacrificial layers 61, 62 located in the detection area Zd, but the chemical etching is performed such that the etching agent does not etch a peripheral portion of the mineral sacrificial layers 61, 62 that extends around the detection area Zd. The non-etched portion of the mineral sacrificial layers 61, 62, on which the upper portion 31.1 of the encapsulating thin layer 31 rests, defines the peripheral area Zp.

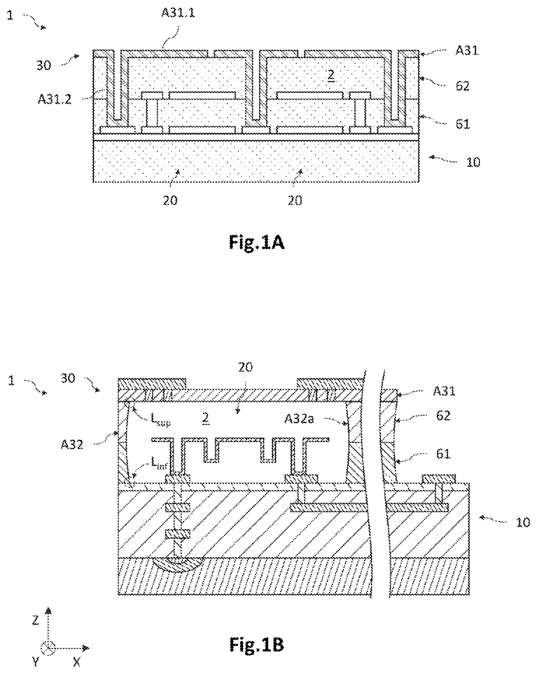

However, the inventors observed that chemically etching the mineral sacrificial layers 61, 62 in an acid medium results in the peripheral wall 32 having a lateral recess, such that the cavity 2 has a vertical enlargement in the plane XY, that is to say that it has a flared shape in the direction +Z. The dimensions of the cavity 2 in the plane XY are greater at the upper portion 31.1 than at the freed surface of the readout substrate 10. This etching profile of the mineral sacrificial layers 61, 62 is thus different from the one illustrated schematically in FIG. 1 of document WO2014/100648A1. It is obtained when the sacrificial layers are made of a mineral material and the etching is chemical etching in an acid medium in a confined environment.

The peripheral wall 32 thus has a side face 32a (that delimits the cavity 2 in the plane XY) that extends vertically in an inclined manner along the axis Z. In other words, the side face 32a has an upper end Lₛᵤₚ located in contact with the upper portion 31.1 of the encapsulating thin layer 31 that is further from the detection area than the lower end L_{inf} located in contact with the readout substrate 10 in a direction opposite to the thermal detectors 20. The upper end Lₛᵤₚ is thus not vertical to the lower end L_{inf}. In a vertical plane passing through the axis Z, the distance between two opposite points of the upper end Lₛᵤₚ is greater than the distance between two opposite points of the lower end L_{inf}. In the figures, this upper lateral recess in the peripheral wall 32 may be monotonic in the direction +Z, or might not be entirely monotonic. It is thus possible for the side face 32a to have a slight return in the direction of the detection area Zd, in particular at the upper portion 31.1.

This upper lateral recess in the peripheral wall 32 is perhaps due to the fact that the chemical attack with an acid medium on mineral sacrificial layers 61, 62, in a confined environment (here due to the presence of the encapsulating thin layer 31), has a lateral etching rate (in the plane XY) greater than the vertical etching rate (along the axis Z). It therefore appears that, in a cavity 2 with a height of approximately 4 μm, the time required to remove the mineral sacrificial layers 61, 62 in the detection area Zd leads to an upper lateral recess of several tens of microns, for example of the order of 40 μm, 60 μm, or even 70 μm.

According to the invention, the presence of this upper lateral recess in the peripheral wall 32 is used to improve the mechanical strength of the encapsulating structure 30, here by locally arranging, around the matrix-array of thermal detectors 20, in the intermediate reinforcement area Zr, reinforcing pillars 31.2 formed in one piece with the upper portion 31.1 of the encapsulating thin layer 31. The reinforcing pillars 31.2 are therefore arranged at the periphery of the cavity 2. There is thus a transmission of mechanical stresses between the encapsulating thin layer 31 and the readout substrate 10, which contributes to improving the mechanical strength of the encapsulating structure 30. This in particular reduces the risks of the encapsulating structure 30 detaching from the readout substrate 10, and more specifically the upper portion 31.1 detaching from the peripheral wall 32. The mechanical strength of the encapsulating structure 30 is also improved when the latter is subjected to a pressure force in the direction −Z due to the fact that the pressure in the cavity 2 may be lower than the pressure of the external environment.

The value of the upper lateral recess (width of the reinforcement area Zr) may be defined as the distance between the lower end L_{inf} and the upper end Lₛᵤₚ, in a direction opposite to the matrix-array of thermal detectors 20, preferably in a plane passing through the axis Z and orthogonal to the side face 32a. This upper lateral recess may be at least equal to several microns or even to several tens of microns. It may thus be greater than or equal to 10 μm, and for example greater than or equal to 25 μm, and for example be of the order of 40 μm. If the sensitive detectors 20 of the matrix-array are arranged periodically at a pitch of approximately 10 μm, it is then possible to produce multiple parallel rows of dummy detectors 40 in the reinforcement area Zr, extending around the detection area Zd. The dummy detectors 40 may then have a structure identical or similar to that of the sensitive detectors 20, the encapsulating thin layer 31 then comprising reinforcing pillars 31.2 resting on the anchoring pillars 41 for the dummy detectors 40.

Furthermore, the side face 32a may form an angle of inclination a less than or equal to 25°, or even less than or equal to 15°, or even less than or equal to 10°, this angle of inclination a being measured at the lower end L_{inf} relative to the plane XY, in the direction of the upper end Lₛᵤₚ. If the upper lateral recess is approximately 40 μm and the height of the cavity 2 (distance along the axis Z between the upper portion 31.1 of the encapsulating thin layer 31 and the readout substrate 10) is approximately 4 μm, this angle of inclination a is equal to approximately 6′.

Furthermore, due to the fact that the encapsulating thin layer 31 comprises reinforcing pillars 31.2 in the reinforcement area Zr, and advantageously support pillars 31.3 in the detection area Zd, the mechanical strength of the encapsulating structure 30 is further increased. It is then possible to reduce the thickness of the encapsulating thin layer 31. This usually has, at the upper portion 31.1, a thickness of for example between 200 nm and 2 μm, for example equal to approximately 800 nm. It is then possible to contemplate further reducing its thickness to less than 800 nm, or even to less than 500 nm, for example to approximately 200 nm.

With reference to FIG. 2F, a sealing layer 34 is deposited on the encapsulating thin layer 31 with a thickness sufficient to ensure the sealing, that is to say the plugging, of the vents 33. It extends at least facing the detection area Zd, since the vents 33 are located there. It preferably completely covers the encapsulating thin layer 31 and therefore extends facing the reinforcement and peripheral areas Zr and Zp. The sealing layer 34 is transparent to the electromagnetic radiation to be detected, and may be made of germanium with a thickness of approximately 1.7 μm. It is also possible to deposit an antireflection layer (not shown) for optimizing the transmission of electromagnetic radiation through the encapsulating structure 30. This antireflection layer may be made of zinc sulfide with a thickness of approximately 1.2 μm.

A hermetic cavity 2 is thus obtained, preferably under vacuum or at reduced pressure, in which the sensitive thermal detectors 20 are housed (in the detection area Zd). The encapsulating structure 30 therefore comprises the encapsulating thin layer 31 and the peripheral wall 32, the latter being formed by the non-etched portion of the sacrificial thin layers 61, 62. Since the peripheral wall 32 (and therefore the cavity 2) has a flared shape, the encapsulating thin layer 31 may then comprise reinforcing pillars 31.2 in the reinforcement area Zr, these resting on the readout substrate 10 (here via the anchoring pillars 41 for the dummy detectors 40). The encapsulating structure 30 therefore has increased mechanical strength.

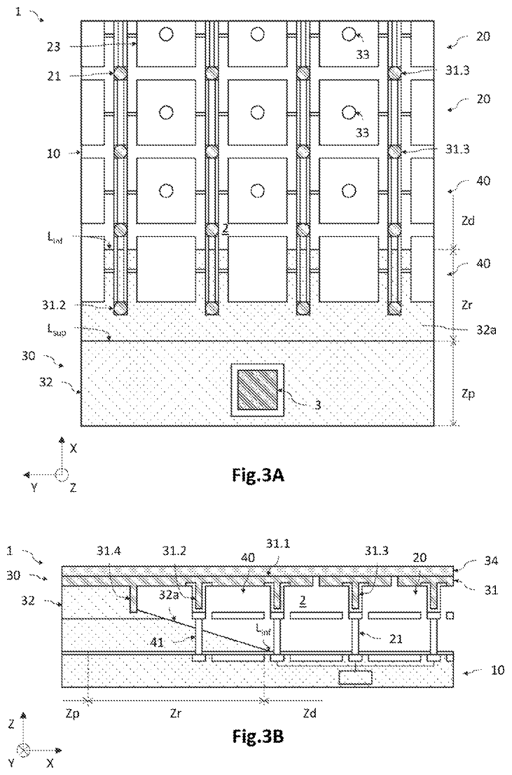

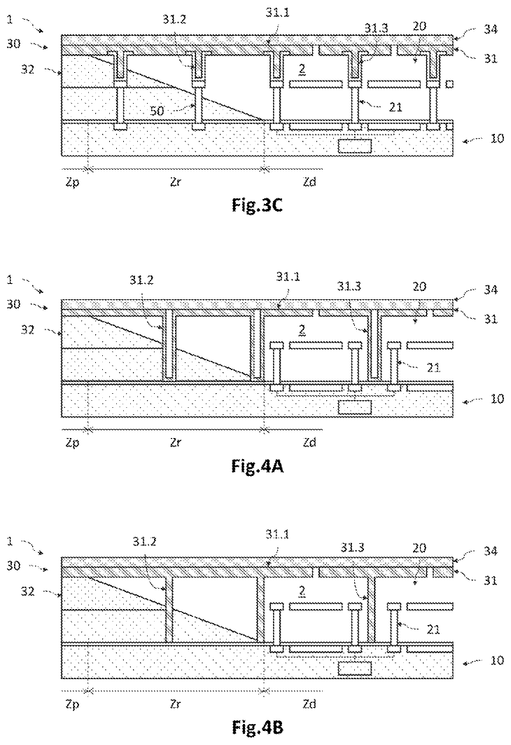

FIG. 3A is a plan, schematic and partial view of a detection device 1 according to one variant of the first embodiment, which is similar to the one described with reference to FIG. 2A to 2F, and differs therefrom essentially only by the number of dummy detectors 40 arranged radially in the reinforcement area Zr. As before, for the sake of clarity, only the border of the detection device 1 is shown. The upper portion 31.1 of the encapsulating thin layer 31 and the sealing thin layer are not shown.

The vents 33 here are arranged only in the detection area Zd, here above each absorbent membrane 23 of the sensitive detectors 20, and make it possible to completely remove the mineral sacrificial layers 61, 62 in the detection area Zd. They may nevertheless be located elsewhere than above the absorbent membranes 23, such as for example above at least some of the anchoring pillars 21. In this example, the encapsulating thin layer 31 (not shown) comprises support pillars 31.3 that rest on the anchoring pillars 21 for the sensitive detectors 20.

No vent is present in the reinforcement area Zr. Therefore, the chemical attack has removed the mineral sacrificial layers 61, 62 from the vents 33 and from the detection area Zd, such that the non-etched portion of the mineral sacrificial layers 61, 62, that is to say the peripheral wall 32, has an inclined side face 32a in the reinforcement area Zr. This upper lateral recess is utilized by arranging reinforcing portions in the reinforcement area Zr resting on the readout substrate 10. In this example, the dummy detectors 40 have a structure and dimensions identical to those of the sensitive detectors 20. A single row of dummy detectors 40 borders the periphery of the detection area Zd here, but multiple rows are possible, depending on the value of the upper lateral recess.

In this example, the peripheral wall 32 extends, outside the cavity 2, so as to completely cover the readout substrate 10. An electrical connection pad 3 (not shown to scale for the sake of clarity) makes it possible to connect the readout circuit to an external electronic device (not shown). This electrical connection pad 3 was initially covered by the mineral sacrificial layers 61, 62, and possibly by the encapsulating thin layer 31 and the sealing thin layer 34. These are then locally removed by dry etching so as to open the electrical connection pad 3 and allow access thereto.

FIG. 3B is a cross-sectional, schematic and partial view of a detection device 1 according to another variant of the first embodiment, which differs from the one described with reference to FIG. 2A to 2F essentially in that the encapsulating thin layer 31 comprises a peripheral portion 31.4 that makes it possible to limit the upper lateral recess of the peripheral wall 32.

This peripheral portion 31.4 is formed in one piece with the upper portion 31.1 during the deposition of the encapsulating thin layer 31. It extends in the direction of the readout substrate 10, but its lower end is free: it does not rest on the readout substrate 10, either directly or indirectly. It may have a height (along the axis Z) substantially equal to the reinforcing pillars 31.2. This peripheral portion 31.4 extends continuously around the detection area Zd, and is located beyond the reinforcing pillars 31.2 in the plane XY. The presence of this peripheral portion 31.4 then makes it possible to reduce the upper lateral recess insofar as it blocks the propagation of the etching agent at the upper portion 31.1 of the encapsulating thin layer 31. Therefore, the side face 32a extends from the lower end L_{inf} of the side surface 32a on the readout substrate 10 to the peripheral portion 31.4.

FIG. 3C is a cross-sectional, schematic and partial view of a detection device 1 according to another variant of the first embodiment, which differs from the one described with reference to FIG. 2A to 2F essentially in that the reinforcing pillars 31.2 do not rest on the anchoring pillars 41 for the dummy detectors 40, but on lower pillars 50, which may be identical or similar to the anchoring pillars 21. It appears that, surprisingly, the lateral recess is smaller in this configuration than in the case of FIG. 2A to 2F. By way of example, it may be of the order of 40 μm rather than 60 to 70 μm.

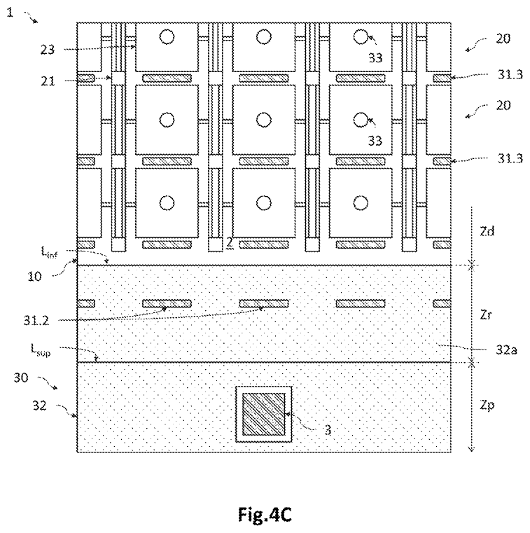

FIGS. 4A and 4B are cross-sectional, schematic and partial views of a detection device 1 according to a second embodiment, in which the reinforcing pillars 31.2 of the encapsulating thin layer 31 come into contact with the readout substrate 10, that is to say that they rest directly on the readout substrate 10, and do not rest on anchoring pillars 41 for dummy detectors 40 or on lower pillars 50. Therefore, the detection device 1 does not comprise any dummy detectors 40 or lower pillars 50 located in the reinforcement area Zr. In these examples, the reinforcing pillars 31.2 are advantageously identical to the support pillars 31.3, which are identical or similar to those described in document EP3067674A2.

With reference to FIG. 4A, the reinforcing pillars 31.2 and the support pillars 31.3 are hollow in the sense that each pillar 31.2, 31.3 is formed of a side wall that delimits, in the plane XY, an internal space that is not filled by the material of the encapsulating thin layer 31. This internal space is at least partially empty. These pillars 31.2, 31.3 are produced by conformal deposition of the encapsulating thin layer 31 into indentations formed in the mineral sacrificial layers 61, 62 that open out onto the readout substrate 10. The dimensions of the indentations in the plane XY and the thickness of the encapsulating thin layer 31 are defined such that the layer portion deposited in the indentations does not fill them and thus forms a side wall that delimits this hollow space.

With reference to FIG. 4B, the reinforcing pillars 31.2 and the support pillars 31.3 are solid, and not hollow, that is to say that each pillar 31.2, 31.3 is formed from one and the same vertical wall the surface of which, in the plane XY, delimits a full space filled with the material of the encapsulating thin layer 31.

In these variant embodiments, a single row of reinforcing pillars 31.2 extends in the reinforcement area Zr around the detection area Zd. However, multiple parallel rows of reinforcing pillars 31.2 are possible, depending on the extent of the lateral recess in the peripheral wall 32, on the one hand, and the radial arrangement pitch of the reinforcing pillars 31.2.

FIG. 4C is a plan, schematic and partial view of the detection device 1 shown in cross section in FIG. 4B. The upper portion 31.1 of the encapsulating thin layer 31 and the sealing thin layer are not shown. The detection area Zd extends to the lower end L_{inf} of the side face 32a of the peripheral wall 32. It is therefore free from any part of the peripheral wall 32, and comprises the matrix-array of sensitive detectors 20. In this example, the support pillars 31.3 are located between two adjacent sensitive detectors 20. A single row of reinforcing pillars 31.2 is provided in the reinforcement area Zr and extends around the detection area in the plane XY, but multiple parallel rows may be provided. The peripheral area Zp comprises the peripheral wall 32 on which the upper portion 31.1 of the encapsulating thin layer 31 is in contact.

Some particular embodiments have just been described. Various variations and modifications will be apparent to those skilled in the art.

1. A method for fabricating a device for detecting electromagnetic radiation, comprising the following steps:
producing a matrix-array of thermal detectors able to detect the electromagnetic radiation, on a readout substrate, through a first mineral sacrificial layer, the thermal detectors and the first mineral sacrificial layer being covered by a second mineral sacrificial layer;
producing an encapsulating structure that delimits a cavity in which the matrix-array of thermal detectors is located, the encapsulating structure being formed of a peripheral wall and of an encapsulating thin layer, by:
depositing the encapsulating thin layer covering the second mineral sacrificial layer;
producing vents in the encapsulating thin layer, located facing the matrix-array of thermal detectors;
partially removing the mineral sacrificial layers, by wet chemical etching in an acid medium, through the vents, so as to free the matrix-array of thermal detectors and to obtain the peripheral wall formed of a non-etched portion of the mineral sacrificial layers, and free an upper portion of the encapsulating thin layer extending above the matrix-array of thermal detectors;
wherein, following the chemical etching step, the peripheral wall has a lateral recess resulting in a vertical enlargement of the cavity, in a plane parallel to the plane of the readout substrate, between the readout substrate and the upper portion, this lateral recess defining an intermediate area of a surface of the readout substrate surrounding the matrix-array of thermal detectors;
the method comprising a step of producing reinforcing pillars of the encapsulating thin layer, arranged in the intermediate area around the matrix-array of thermal detectors, separate from one another and extending from the upper portion until resting on the readout substrate.

2. The fabrication method as claimed in claim 1, wherein the peripheral wall has a side face laterally delimiting the cavity, the side face extending vertically between a lower end in contact with the readout substrate and an upper end in contact with the upper portion, the upper end being spaced from the lower end, in a plane parallel to the plane of the readout substrate and in a direction opposite to the matrix-array of thermal detectors, by a distance greater than or equal to 10 μm.

3. The fabrication method as claimed in claim 1, wherein the upper portion of the encapsulating thin layer has a thickness less than or equal to 800 nm.

4. The fabrication method as claimed in claim 1, wherein the reinforcing pillars are arranged in multiple rows parallel to one another, which extend around the matrix-array of thermal detectors.

5. The fabrication method as claimed in claim 1, wherein the thermal detectors comprise an absorbent membrane suspended above the readout substrate by anchoring pillars, and wherein the reinforcing pillars rest indirectly on the readout substrate, being in contact with lower pillars (41, 50) extending from the readout substrate, the lower pillars having the same height as that of the anchoring pillars.

6. The fabrication method as claimed in claim 5, wherein the lower pillars are anchoring pillars for what are known as dummy detectors not able to detect electromagnetic radiation, the anchoring pillars for each dummy detector holding a suspended membrane.

7. The fabrication method as claimed in claim 6, wherein the dummy detectors have a structure and dimensions identical to those of the thermal detectors of the matrix-array.

8. The fabrication method as claimed in claim 5, wherein the encapsulating thin layer comprises support pillars, arranged facing the matrix-array of thermal detectors, separate from one another and extending from the upper portion until resting on anchoring pillars for the thermal detectors, the anchoring pillars for each thermal detector holding a suspended membrane.

9. The fabrication method as claimed in claim 8, wherein insulating portions, made of an electrically insulating material, are arranged between and in contact with the support pillars and the anchoring pillars for the thermal detectors.

10. The fabrication method as claimed in claim 1, wherein the reinforcing pillars rest directly on the readout substrate, being in contact with the readout substrate.

11. The fabrication method as claimed in claim 10, wherein the encapsulating thin layer comprises support pillars, separate from one another and extending from the upper portion until resting on and in contact with the readout substrate, each arranged between two adjacent thermal detectors.

12. The fabrication method as claimed in claim 8, wherein the reinforcing pillars and the support pillars have an identical structure and identical dimensions.

13. The fabrication method as claimed in claim 1, wherein the encapsulating thin layer comprises a peripheral portion, extending continuously around the matrix-array of thermal detectors, and arranged beyond the reinforcing pillars, in a plane parallel to the readout substrate and in a direction opposite to the matrix-array of thermal detectors, and extending from the upper portion in the direction of the readout substrate over part of the height of the cavity.

14. The fabrication method as claimed in claim 1, wherein the wet chemical etching is carried out with hydrofluoric acid in the vapor phase, and the mineral sacrificial layers (61, 62) are made of a silicon-based material.

15. A device for detecting electromagnetic radiation, comprising:
a readout substrate;
a matrix-array of thermal detectors, resting on the readout substrate;
an encapsulating structure, delimiting a cavity in which the matrix-array of thermal detectors is located, and comprising:
a peripheral wall, made of a mineral material, and laterally delimiting the cavity;
an encapsulating thin layer, comprising an upper portion extending above the matrix-array of thermal detectors and resting on the peripheral wall;
wherein:
the peripheral wall has a lateral recess resulting in a vertical enlargement of the cavity, in a plane parallel to the readout substrate, between the readout substrate and the upper portion, this lateral recess defining an intermediate area of a surface of the readout substrate surrounding the matrix-array of thermal detectors;
the encapsulating thin layer comprises reinforcing pillars, arranged in the intermediate area around the matrix-array of thermal detectors, separate from one another and extending from the upper portion until resting on the readout substrate.
